(19) United States
(12) Patent Application Publication
(10) Pub. No.: US 2011/0204525 A1
(43) Pub. Date: Aug. 25, 2011

(54) SEMICONDUCTOR DEVICE AND FABRICATION METHOD FOR THE SAME

(75) Inventor: Kouhei SEO, Toyama (JP)

(73) Assignee: PANASONIC CORPORATION, Osaka (JP)

(21) Appl. No.: 13/097,541

(22) Filed: Apr. 29, 2011

Related U.S. Application Data
(63) Continuation of application No. PCT/JP2009/005668, filed on Oct. 27, 2009.

(30) Foreign Application Priority Data
Jan. 13, 2009 (JP) 2009-004486

(51) Int. Cl. H01L 23/48; H01L 21/28

(52) U.S. Cl. 257/774; 438/618; 438/778; 257/E21.158; 257/E23.011

(57) ABSTRACT

An interlayer insulating film containing a pore-forming agent is formed on a semiconductor substrate, and then the interlayer insulating film is irradiated with ultraviolet (UV). This ultraviolet irradiation is performed in at least two separate times.

### CROSS-REFERENCE TO RELATED APPLICATION

This is a continuation of PCT International Application PCT/JP2009/005668 filed on Oct. 27, 2009, which claims priority to Japanese Patent Application No. 2009-004486 filed on Jan. 13, 2009. The disclosures of these applications including the specifications, the drawings, and the claims are hereby incorporated by reference in their entirety.

### BACKGROUND

The present disclosure relates to a semiconductor device and a fabrication method for the same, and more particularly to an interconnect technology for forming interconnects in an interlayer insulating film.

In recent years, with the scaling-down of the dimensions of interconnects accompanying the high integration of semiconductor devices, the capacitance between adjacent interconnects has increased, so that the RC delay of interconnects has raised a problem. For this reason, there have been requests for reduction in the dielectric constant of an interlayer insulating film. As one method for reducing the dielectric constant of an interlayer insulating film, known is a technique of forming a number of pores in an insulating film using a pore-forming agent. To remove the pore-forming agent, thermal annealing, ultraviolet (UV) irradiation, etc. may be used. From the standpoint of improving the throughput of a semiconductor fabrication apparatus, removal of the pore-forming agent by UV irradiation is considered effective. However, since pores are formed in the insulating film for reduction in dielectric constant, the mechanical strength of the film extremely decreases, causing degradation in the yield of interconnects, reliability, and assembly endurance. As a technique for solving this problem, known is film curing by UV irradiation (UV cure) from the standpoint of improving the throughput of a semiconductor fabrication apparatus, as described in WO/2007/043206 (Patent Document 1).

### SUMMARY

Conventionally, when pores are formed in an insulating film using a pore-forming agent and the insulating film is irradiated with UV, without consideration of its wavelength, for increasing the mechanical strength of the film, the interlayer insulating film absorbs moisture due to damage caused by cleavage of chemical bonds in the film. This increases the relative dielectric constant and moreover, with moisture acting as a leakage path, degrades the voltage resistance between adjacent interconnects, causing problems of greatly decreasing the yield and reliability of the semiconductor device.

It is an objective of the present disclosure to provide a semiconductor device that includes metal interconnects (e.g., copper interconnects) formed in a low dielectric-constant insulating film containing pores and yet has high yield, high reliability, and high performance.

To attain the above objective, in the fabrication method for a semiconductor device of the present disclosure, at least two times of UV irradiation different in wavelength are performed during formation of a low dielectric-constant insulating film containing pores.

More specifically, the semiconductor device of the present disclosure includes: a first interlayer insulating film formed on a semiconductor substrate, a plurality of first interconnects being formed in the first interlayer insulating film; and a second interlayer insulating film formed on the first interlayer insulating film, a plurality of second interconnects being formed in the second interlayer insulating film, wherein the dielectric constant of the first interlayer insulating film is lower than the dielectric constant of the second interlayer insulating film.

According to the semiconductor device of the present disclosure, an insulating film low in dielectric constant is used for a lower-layer interlayer insulating film of the semiconductor device to achieve high-speed operation and low power. For an upper-layer interlayer insulating film, an insulating film whose dielectric constant is not so low is used because upper-layer interconnects are wider in line width and spacing between interconnects than lower-layer interconnects, and thus the RC delay of interconnects does not raise a big problem. With this configuration, the fabrication cost can be reduced for an upper-layer interlayer insulating film.

In the semiconductor device of the present disclosure, preferably, at least the first interlayer insulating film has pores, and the porosity of the first interlayer insulating film is higher than the porosity of the second interlayer insulating film.

The above configuration ensures reduction in the dielectric constant of the first interlayer insulating film that is a lower-layer film.

In the semiconductor device of the present disclosure, preferably, the film strength of the second interlayer insulating film is higher than the film strength of the first interlayer insulating film.

The above configuration further improves the assembly endurance.

In the semiconductor device of the present disclosure, preferably, the spacing between the first interconnects is smaller than the spacing between the second interconnects.

Since an insulating film low in dielectric constant is used for the first interlayer insulating film in which interconnects are formed with reduced spacing between interconnects, high-speed operation and low power can be achieved.

In the semiconductor device of the present disclosure, preferably, a plurality of pores are formed in the first interlayer insulating film by removing a pore-forming agent.

In the semiconductor device of the present disclosure, preferably, the first interlayer insulating film is a carbon-containing silicon oxide film having a plurality of pores formed by removing a pore-forming agent.

In the semiconductor device of the present disclosure, preferably, the second interlayer insulating film is a silicon oxide film or a carbon-containing silicon oxide film.

The first fabrication method for a semiconductor device of the present disclosure includes the steps of: (a) forming a first interlayer insulating film containing a pore-forming agent on a semiconductor substrate; and (b) irradiating the first interlayer insulating film with ultraviolet, wherein the step (b) includes performing the ultraviolet irradiation in at least two separate times.

According to the first fabrication method for a semiconductor device, the first interlayer insulating film is irradiated with ultraviolet in at least two separate times in the irradiation process. Therefore, by the multi-stage irradiation with wavelengths changed every time, reduction in dielectric constant and enhancement in mechanical strength can be attained simultaneously.

In the first fabrication method for a semiconductor device, preferably, the step (b) includes the steps of (b1) irradiating the first interlayer insulating film with first ultraviolet to remove the pore-forming agent contained in the first interlayer insulating film, and (b2) irradiating the first interlayer insulating film with second ultraviolet to enhance the mechanical strength of the first interlayer insulating film, and a wavelength of the first ultraviolet in the step (b1) and a wavelength of the second ultraviolet in the step (b2) are different from each other.

In the above case, preferably, the wavelength of the first ultraviolet is shorter than the wavelength of the second ultraviolet.

Since the removal of the pore-forming agent is faster as the ultraviolet wavelength is shorter, the throughput improves and the fabrication cost can be reduced.

In the above case, preferably, the first ultraviolet is ultraviolet having a wavelength in a range of 150 nm to 200 nm as a main component, and the second ultraviolet is ultraviolet having a wavelength in a range of 200 nm to 300 nm as a main component.

With an ultraviolet wavelength of 200 nm or less, the pore-forming agent can be removed fast, and with an ultraviolet wavelength of 200 nm or more, the film strength can be enhanced without causing any damage.

In the above case, preferably, the step (b) further includes the step of (b3) irradiating the first interlayer insulating film with third ultraviolet to remove a damage bond generated in the first interlayer insulating film, and a wavelength of the second ultraviolet in the step (b2) and a wavelength of the third ultraviolet in the step (b3) are different from each other.

With irradiation of the third ultraviolet, damage bonds, which may be generated in the first interlayer insulating film causing increase in dielectric constant, can be removed, and thus increase in the dielectric constant of the first interlayer insulating film can be suppressed or reduced.

In the above case, preferably, the wavelength of the first ultraviolet is shorter than the wavelength of the third ultraviolet.

In the above case, preferably the third ultraviolet is ultraviolet having a wavelength in a range of 300 nm to 500 nm as a main component.

With such third ultraviolet, damage bonds generated in the first interlayer insulating film can be removed nearly completely.

In the first fabrication method for a semiconductor device, preferably, the first interlayer insulating film has a relative dielectric constant of 2.5 or less and a pore diameter of 0.8 nm or more.

In the first fabrication method for a semiconductor device, the pore-forming agent can be a hydrocarbon-based material.

The first fabrication method for a semiconductor device may further include the step of: (c) forming a plurality of first interconnects in the first interlayer insulating film before the step (b).

The method described above may further include, after the step (c), the steps of: (d) forming a second interlayer insulating film on the first interlayer insulating film; and (e) forming a plurality of second interconnects in the second interlayer insulating film, wherein in the step (e), the second interlayer insulating film is not subjected to the ultraviolet irradiation in at least two separate times.

With the above arrangement, an insulating film low in dielectric constant can be formed for a lower-layer interlayer insulating film of the semiconductor device to achieve high-speed operation and low power. For an upper-layer interlayer insulating film, an insulating film whose dielectric constant is not so low can be used because upper-layer interconnects are wider in line width and spacing between interconnects than lower-layer interconnects, and thus the RC delay of interconnects does not raise a big problem. Thus, the fabrication cost can be reduced for an upper-layer interlayer insulating film.

In the above case, preferably, in the step (e), the second interlayer insulating film is not subjected to ultraviolet irradiation.

In the above case, preferably, the spacing between the first interconnects is smaller than the spacing between the second interconnects.

Since an insulating film low in dielectric constant is used for the first interlayer insulating film in which interconnects are formed with reduced spacing between interconnects, high-speed operation and low power can be achieved.

In the first fabrication method for a semiconductor device, a light source for the ultraviolet in the step (b) may be of a single type.

In the first fabrication method for a semiconductor device, preferably, the ultraviolet irradiation in at least two separate times in the step (b) is performed continuously in a same apparatus.

In the first fabrication method for a semiconductor device, in the step (b), the ultraviolet irradiation may be performed via a spectroscopic device configured to disperse the ultraviolet, placed between an ultraviolet lamp as a light source and the semiconductor substrate.

In the above case, the spectroscopic device may include a diffraction grating, and the ultraviolet may be dispersed by adjusting the angle of the diffraction grating.

In the first fabrication method for a semiconductor device, in the step (b), the ultraviolet irradiation may be performed via a filter placed between an ultraviolet lamp as a light source and the semiconductor substrate.

In the above case, the filter may be placed movably in an in-plane direction of the principal plane of the semiconductor substrate.

In the first fabrication method for a semiconductor device, in the step (b), the ultraviolet irradiation may be performed via a gas provided between an ultraviolet lamp as a light source and the semiconductor substrate.

In the above case, the gas may be allowed to flow between the ultraviolet lamp and the semiconductor substrate.

In the first fabrication method for a semiconductor device, the step (b) may be executed by a fabrication apparatus including a configuration permitting irradiation using first ultraviolet having a wavelength effective in speeding up the removal of the pore-forming agent, a configuration permitting irradiation using second ultraviolet having a wavelength effective in enhancing the mechanical strength of the first interlayer insulating film, and a configuration permitting irradiation using third ultraviolet having a wavelength effective in removing a damage bond generated in the first interlayer insulating film.

The second fabrication method for a semiconductor device of the present disclosure includes the steps of: (a) forming an interlayer insulating film containing a pore-forming agent on a semiconductor substrate; and (b) irradiating the interlayer insulating film with ultraviolet, wherein in the step (b), the ultraviolet has a wavelength in a range of 180 nm to 200 nm as a main component.

According to the second fabrication method for a semiconductor device, the interlayer insulating film is irradiated with ultraviolet having a wavelength in the range of 180 nm to 200 nm as a main component. Therefore, removal of the pore-forming agent and enhancement in the mechanical strength of the interlayer insulating film can be achieved simultaneously without the necessity of performing multi-stage irradiation in at least two separate times.

In the second fabrication method for a semiconductor device, in the step (b), the ultraviolet irradiation is preferably performed to remove the pore-forming agent contained in the interlayer insulating film and also enhance the mechanical strength of the interlayer insulating film.

It goes without mentioning that the features described above can be combined appropriately as far as no contradiction occurs in such a combination. Note that, when a plurality of effects are expected from any of the above features, it is not necessarily required to exert all of such effects.

According to the semiconductor device and the fabrication method for the same of the present disclosure, while the dielectric constant of an interlayer insulating film containing a pore-forming agent can be reduced due to pores formed therein, the mechanical strength thereof can be enhanced simultaneously. Therefore, since increase in relative dielectric constant and degradation in voltage resistance between interconnects due to moisture absorption are suppressed or reduced, it is possible to prevent reduction in the yield and reliability of the semiconductor device.

### BRIEF DESCRIPTION OF THE DRAWINGS

FIG. 1 is a cross-sectional view of a main portion of a semiconductor device of an embodiment of the present disclosure.

FIGS. 2A-2J are cross-sectional views showing steps of a first fabrication method for the semiconductor device of the embodiment of the present disclosure.

FIGS. 3A-3F are cross-sectional views showing steps of the first fabrication method for the semiconductor device of the embodiment of the present disclosure.

FIG. 4A is a graph showing UV wavelength dependence of the removal rate of a pore-forming agent. FIG. 4B is a graph showing UV wavelength dependence of the increase rate of film strength. FIG. 4C is a graph showing UV wavelength dependence of the damage bond amount in the film.

FIGS. 5A-5K are cross-sectional views showing steps of a second fabrication method for the semiconductor device of the embodiment of the present disclosure.

FIGS. 6A-6F are cross-sectional views showing steps of the second fabrication method for the semiconductor device of the embodiment of the present disclosure.

FIG. 7A is a graph showing UV wavelength dependence of the removal rate of a pore-forming agent. FIG. 7B is a graph showing UV wavelength dependence of the increase rate of film strength. FIG. 7C is a graph showing UV wavelength dependence of the damage bond amount in the film.

FIGS. 8A and 8B are schematic cross-sectional views illustrating a first fabrication apparatus provided with a spectroscopic device, for implementing the first and second methods for fabricating the semiconductor device of the embodiment of the present disclosure.

FIG. 9 is a schematic cross-sectional view illustrating a second fabrication apparatus provided with a filter, for implementing the first and second methods for fabricating the semiconductor device of the embodiment of the present disclosure.

FIG. 10 is a schematic cross-sectional view illustrating a third fabrication apparatus provided with a filter chamber, for implementing the first and second methods for fabricating the semiconductor device of the embodiment of the present disclosure.

FIGS. 11A-11I are cross-sectional views showing steps of a third fabrication method for the semiconductor device of the embodiment of the present disclosure.

FIGS. 12A-12F are cross-sectional views showing steps of the third fabrication method for the semiconductor device of the embodiment of the present disclosure.

FIG. 13A is a graph showing UV wavelength dependence of the removal rate of a pore-forming agent. FIG. 13B is a graph showing UV wavelength dependence of the increase rate of film strength. FIG. 13C is a graph showing UV wavelength dependence of the damage bond amount in the film.

### DETAILED DESCRIPTION

### Embodiment

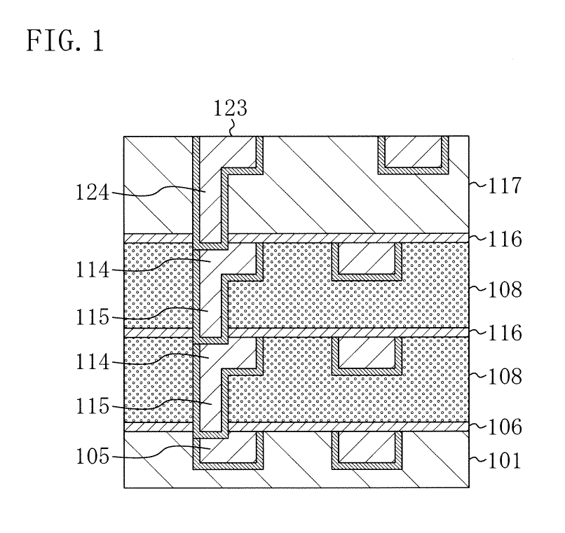

A semiconductor device of an embodiment of the present disclosure will be described with reference to FIG. 1. It should be noted that the materials and the values used in the present disclosure are not restrictive, but merely represent preferred examples, and that modifications can be made appropriately without departing from the spirit and scope of the present disclosure.

As shown in FIG. 1, the semiconductor device of this embodiment includes a first structure, a second structure, and a third structure formed in this order on a semiconductor substrate (not shown) made of silicon (Si), for example, on which a plurality of semiconductor elements are formed.

The first structure includes a first interlayer insulating film 101 and first interconnects 105 formed in the first interlayer insulating film 101.

The second structure includes: a first liner film 106 formed on the first structure; a second interlayer insulating film 108 formed on the first liner film 106; first vias 115 formed in the second interlayer insulating film 108; and second interconnects 114 formed in the second interlayer insulating film 108 and connected with the first vias 115. The second structure is actually a layered structure having two layers substantially the same in structure stacked one upon the other. A liner film 116 is interposed between the two interconnect structures.

The third structure includes: a second liner film 116 formed on the second structure; a fourth interlayer insulating film 117 formed on the second liner film 116; second vias 124 formed in the fourth interlayer insulating film 117; and third interconnects 123 farmed in the fourth interlayer insulating film 117 and connected with the second vias 124.

The second interlayer insulating film 108 of the second structure is lower in dielectric constant than the fourth interlayer insulating film 117 of the third structure. That is, the second interlayer insulating film 108 is comprised of an insulating film having a number of pores, or to be more specific, an insulating film formed by removing a pore-forming agent (e.g., porogen) from a carbon-containing silicon oxide (SiOC) containing the pore-forming agent. Conversely, the fourth interlayer insulating film 117 is comprised of a silicon dioxide (SiO₂) film or a SiOC film containing no pore-forming agent. Accordingly, the second interlayer insulating film 108 is higher in porosity and lower in dielectric constant than the fourth interlayer insulating film 117. Also, the fourth interlayer insulating film 117, which is lower in porosity than the second interlayer insulating film 108, is higher in film strength than the second interlayer insulating film 108. The second interlayer insulating film 108 has a relative dielectric constant of about 2.3 to about 2.5, an average pore diameter of about 0.8 nm or more, and a modulus of elasticity of about 6 GPa to about 8 GPa or more. The fourth interlayer insulating film 117 has a relative dielectric constant of about 2.7 or more.

As described above, in this embodiment, an insulating material low in dielectric constant is used for a lower-layer interlayer insulating film, i.e., the second interlayer insulating film 108 in the illustrated example, for which high-speed operation and low power are highly requested. Conversely, an insulating material whose dielectric constant is not so low is used for an upper-layer interlayer insulating film, i.e., the fourth interlayer insulating film 117 in the illustrated example, for which high-speed operation and low power are not so requested. This configuration provides an advantage that the cost for reducing the dielectric constant of an upper-layer interlayer insulating film can be reduced.

Also, as shown in FIG. 1, the second interconnects 114 of the second structure are arranged to have shorter spacing therebetween than the third interconnects 123 of the third structure. This is because, the shorter the spacing between interconnects, the higher the necessity of reducing the dielectric constant between the interconnects is.

Although the two-layered structure is illustrated as the second structure, three or more layered structure may be used. Although one-layer structure is illustrated as the third structure, two or more layered structure may be used.

It is preferable that the first interlayer insulating film 101 is an insulating film made of SiOC having a thickness of 200 nm, and the first liner 106 is a multilayer insulating film made of oxygen-containing silicon carbide (SiCO) and nitrogen-containing silicon carbide (SiCN), both having a thickness of about 30 nm, stacked one upon the other.

It is preferable that the second interlayer insulating film 108 has a thickness of about 200 nm, and the second liner film 116 is an insulating film made of SiCN having a thickness of about 60 nm.

It is also preferable to provide a barrier film comprised of a single-layer film or a multilayer film made of any of tantalum (Ta), titanium (Ti), ruthenium (Ru), nitrides thereof, alloys thereof, etc. on the sides and bottoms of the first interconnects 105, the second interconnects 114, and the third interconnects 123 and the sides and bottoms of the first vias 115 and the second vias 124.

The interconnects 105, 114, and 123 and the vias 115 and 124 are preferably made of any of copper (Cu), silver (Ag), aluminum (Al), alloys thereof, etc.

(First Fabrication Method of Embodiment)

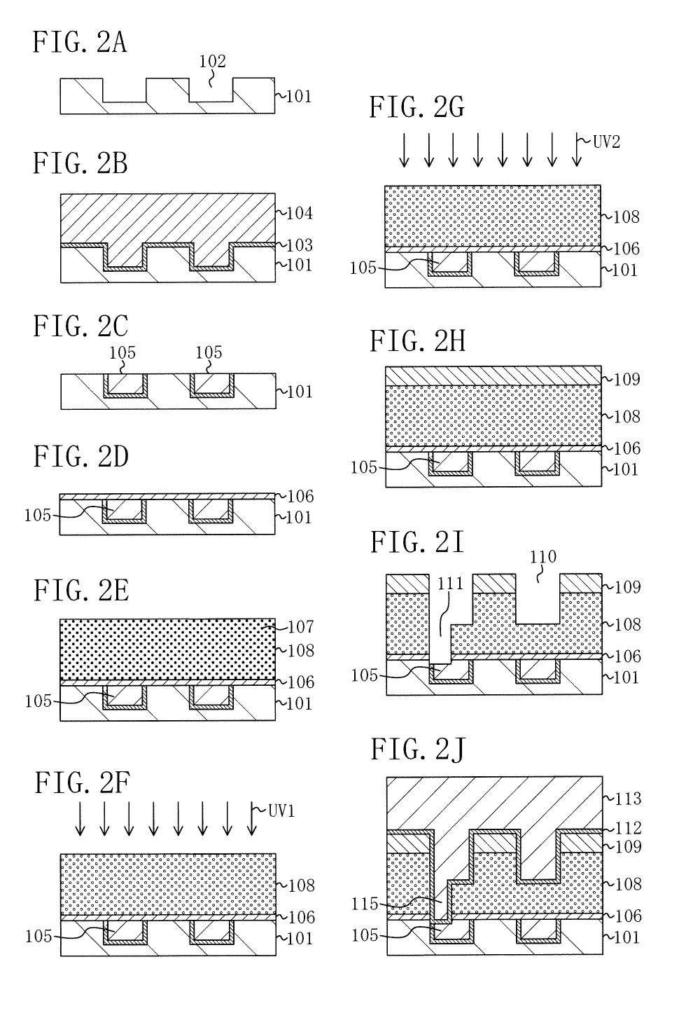

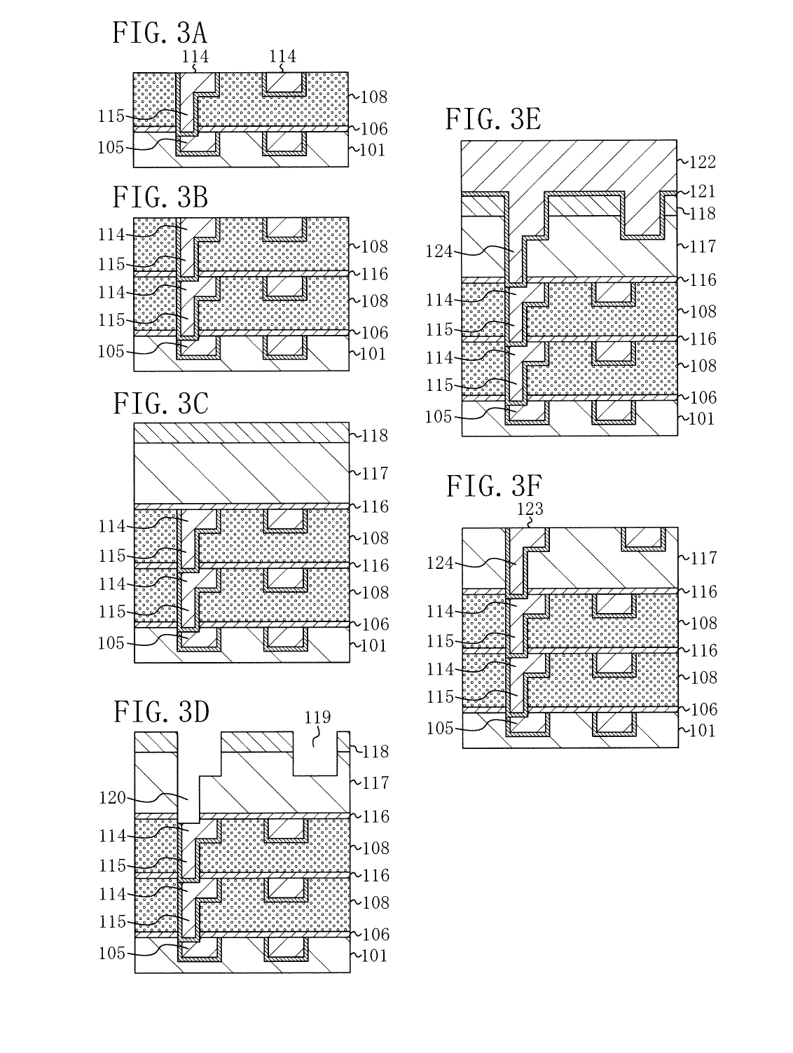

A first fabrication method for the semiconductor device of the embodiment of the present disclosure will be described with reference to FIGS. 2A-2J and 3A-3F. It should be noted that the materials and the values used in this fabrication method are not restrictive, but merely represent preferred examples, and that modifications can be made appropriately without departing from the spirit and scope of the present disclosure.

FIGS. 2A-2J and 3A-3F show cross-sectional configurations at steps of the first fabrication method for the semiconductor device of this embodiment.

First, as shown in FIG. 2A, the first interlayer insulating film 101 made of SiOC having a thickness of about 200 nm is deposited, by chemical vapor deposition (CVD), for example, on a semiconductor substrate (not shown) made of silicon (Si) on which a plurality of semiconductor elements are formed. Subsequently, a plurality of first grooves 102 for formation of first interconnects are formed spaced from each other in the first interlayer insulating film 101 by lithography and dry etching.

As shown in FIG. 2B, a barrier film 103 made of tantalum (Ta)/tantalum nitride (TaN) and a copper film 104 are deposited sequentially over the entire surface of the first interlayer insulating film 101 including the first grooves 102 by sputtering and plating. Although the Ta/TaN layered film is used as the barrier film 103 in the illustrated fabrication method, a single-layer film or a multilayer film made of any of Ta, Ti, Ru, nitrides thereof, alloys thereof, etc. may be used. Also, although copper (Cu) is used as the conductive film for filling of the first grooves 102 in the illustrated fabrication method, any of silver (Ag), aluminum (Al), alloys thereof, etc. may be used.

As shown in FIG. 2C, unnecessary portions of the barrier film 103 and the copper film 104 deposited on the area of the first interlayer insulating film 101 excluding the portions of the first grooves 102 are removed by chemical mechanical polishing (CMP). As a result, the first interconnect 105 comprised of the barrier film 103 and the copper film 104 is formed in each of the first grooves 102.

As shown in FIG. 2D, the first liner film 106 comprised of a multilayer film of SiCO/SiCN each having a thickness of about 30 nm is formed over the entire surface of the first interlayer insulating film 101 including the first interconnects 105 by CVD, for example.

As shown in FIG. 2E, a SiOC film 108 containing a pore-forming agent 107, having a thickness of about 200 nm, is formed on the first liner film 106 as the second interlayer insulating film.

As shown in FIG. 2F, the SiOC film 108 is irradiated with first ultraviolet UV1 (first UV irradiation) to remove the pore-forming agent 107, thereby forming a plurality of pores in the SiOC film 108. The first ultraviolet UV1 includes wavelength components of about 200 nm or less in a light quantity extremely large compared with wavelength components of more than about 200 mm, and has an illumination of about 100 mW/cm² to about 200 mW/cm². The resultant pore-formed SiOC film 108 has a relative dielectric constant of about 2.3 to about 2.5 and a modulus of elasticity of about 6 GPa to about 8 GPa, or less than this range. As the pore-forming agent 107, other than porogen, α-terpinene, which is a hydrocarbon-based material, can be used. In this fabrication method, the removal rate of the pore-forming agent is improved by irradiation with short-wavelength UV light. This provides a merit of improving the throughput of a semiconductor fabrication apparatus.

As shown in FIG. 2G, the SiOC film 108 is then irradiated with second ultraviolet UV2 different in wavelength from the first ultraviolet UV1 (second UV irradiation) to enhance the mechanical strength of the SiOC film 108. The second ultraviolet UV2 includes wavelength components of about 200 nm or more in a light quantity extremely large compared with wavelength components of less than about 200 mm, and has an illumination of 100 mW/cm² to about 200 mW/cm². The resultant SiOC film 108 after the irradiation with the second ultraviolet UV2 has a relative dielectric constant of about 2.3 to about 2.5 and a modulus of elasticity of about 6 GPa to about 8 GPa or more. With this multi-stage UV irradiation performed in a plurality of separate times, the second interlayer insulating film 108 with low dielectric constant and high strength can be obtained. The average diameter of pores finally formed in the second interlayer insulating film 108 is about 0.8 nm or more.

In the multi-stage UV irradiation, in which the roles played in changing the film quality are different between the wavelengths, an equal film quality can be obtained even when the order of wavelengths used is changed, i.e., when the second interlayer insulating film 108 is irradiated first with the second ultraviolet UV2 and then with the first ultraviolet UV1. Since the capacitance between interconnects can be reduced with decrease in the relative dielectric constant of the second interlayer insulating film 108, high-speed operation and low power can be achieved for the semiconductor device.

As shown in FIG. 2H, a third interlayer insulating film 109 made of SiO₂ having a thickness of about 100 nm is formed on the second interlayer insulating film 108. As the SiO₂ third interlayer insulating film 109, an insulating film made of SiOC having a relative dielectric constant of about 2.7 or more, or a multilayer film thereof, may be used. When being used as a hard mask during processing, the SiO₂ third interlayer insulating film 109 may be a multilayer film including a metal film made of TiN, TaN, etc. formed on the insulating film made of SiO₂ or SiOC. By forming the third interlayer insulating film 109 on the second interlayer insulation film 108, it is possible to suppress or reduce reforming of the second interlayer insulating film 108 by plasma-emitted light during subsequent etching or ashing process. Also, since the second interlayer insulating film 108 has been strengthened by the multi-stage UV irradiation before the etching or ashing process, the resistance against plasma damage due to etching or ashing improves. As a result, the capacitance between interconnects can be further reduced.

As shown in FIG. 2I, a plurality of second grooves 110 for formation of second interconnects are formed spaced from each other in the second interlayer insulating film 108 through the third interlayer insulating film 109 by lithography and dry etching. Subsequently, first holes 111 for formation of first vias are formed through the first liner 106 and the second interlayer insulating film 108 so as to be connected with the first interconnects 105.

As shown in FIG. 2J, a barrier film 112 made of tantalum (Ta)/tantalum nitride (TaN) and a copper film 113 are deposited sequentially over the entire surface of the third interlayer insulating film 109 including the second grooves 110 and the first holes 111 by sputtering and plating. Although the Ta/TaN layered film is used as the barrier film 112 in the illustrated fabrication method, a single-layer film or a multilayer film made of any of Ta, Ti, Ru, nitrides thereof, alloys thereof, etc. may be used. Also, although copper (Cu) is used as the conductive film for filling of the second grooves 110 and the first holes 111 in the illustrated fabrication method, any of silver (Ag), aluminum (Al), alloys thereof, etc. may be used.

As shown in FIG. 3A, unnecessary portions of the barrier film 112 and the copper film 113 deposited on the area of the third interlayer insulating film 109 excluding the portions of the second grooves 110, as well as the third interlayer insulating film 109, are removed by chemical mechanical polishing (CMP). Also, a top portion of the second interlayer insulating film 108 is polished away by about 20 nm, thereby to form the second interconnect 114 and the first via 115, each comprised of the barrier film 112 and the copper film 113, in each of the second grooves 110 and each of the first holes 111, respectively.

Thereafter, a series of steps shown in FIGS. 2D-2J and 3A is repeated, to form a three-layer interconnect structure shown in FIG. 3B.

As shown in FIG. 3C, the second liner film 116 made of SiCN having a thickness of about 60 nm is formed over the entire top surface of the three-layer structure by CVD, for example. Subsequently, the fourth interlayer insulating film 117 made of SiOC having a thickness of about 400 nm is formed on the second liner film 116, and then a fifth interlayer insulating film 118 made of SiO₂ having a thickness of about 100 nm is formed on the fourth interlayer insulating film 117. Although SiCN is used for the second liner film in the illustrated fabrication method, SiN may be used. For the SiOC fourth interlayer insulating film 117, it is advisable to use a SiOC film having a relative dielectric constant of about 2.7 or more.

As shown in FIG. 3D, third grooves 119 for formation of third interconnects are formed in the fourth interlayer insulating film 117 through the fifth interlayer insulating film 118 by lithography and dry etching. Subsequently, second holes 120 for formation of second vias are formed selectively through the second liner film 116 and the fourth interlayer insulating film 117 so as to be connected with the second interconnects 114.

As shown in FIG. 3E, a barrier film 121 made of tantalum (Ta)/tantalum nitride (TaN) and a copper film 122 are deposited sequentially over the entire surface of the fifth interlayer insulating film 118 including the third grooves 119 and the second holes 120 by sputtering and plating. Although the Ta/TaN layered film is used as the barrier film 121 in the illustrated fabrication method, a single-layer film or a multilayer film made of any of Ta, Ti, Ru, nitrides thereof, alloys thereof, etc. may be used. Also, although copper (Cu) is used as the conductive film for filling of the third grooves 119 and the second holes 120 in the illustrated fabrication method, any of silver (Ag), aluminum (Al), alloys thereof, etc. may be used.

As shown in FIG. 3F, unnecessary portions of the barrier film 121 and the copper film 122 deposited on the area of the fifth interlayer insulating film 118 excluding the portions of the third grooves 119, as well as the fifth interlayer insulating film 118, are removed by chemical mechanical polishing (CMP). Also, a top portion of the fourth interlayer insulating film 117 is polished away by about 20 nm, thereby to form the third interconnect 123 and the second via 124, each comprised of the barrier film 121 and the copper film 122, in each of the third grooves 119 and each of the second holes 120, respectively.

In the four-layer structure shown in FIG. 3F, an interlayer insulating film low in relative dielectric constant is required for the second interconnects 114 formed in the two intermediate layers, i.e., the second interlayer insulating films 108, to achieve high-speed operation and low power. Conversely, since the third interconnects 123 formed in the fourth interlayer insulating film 117 located above the second interlayer insulating films 108 only need to supply power stably, an interlayer insulating film low in relative dielectric constant is not necessarily required for the third interconnects 123. Note that although interlayer insulating films low in relative dielectric constant are used for the two intermediate layers of the four-layer structure in the illustrated fabrication method, the use of such a low dielectric-constant film is not limited to this, but varies depending on the required specifications of the semiconductor device.

As described above, in the first fabrication method, the multi-stage UV irradiation is performed for the second interlayer insulating films 108 containing the pore-forming agent 107. More specifically, the first UV irradiation is performed using the first ultraviolet UV1 having wavelengths effective in speeding up the removal of the pore-forming agent, and then the second UV irradiation is performed using the second ultraviolet UV2 having wavelengths effective in enhancing the mechanical strength of the second interlayer insulating film 108. The first ultraviolet UV1 used in the first UV irradiation and the second ultraviolet UV2 used in the second UV irradiation are different in wavelength from each other as described above. Therefore, reduction in dielectric constant and enhancement in mechanical strength can be achieved with good throughput.

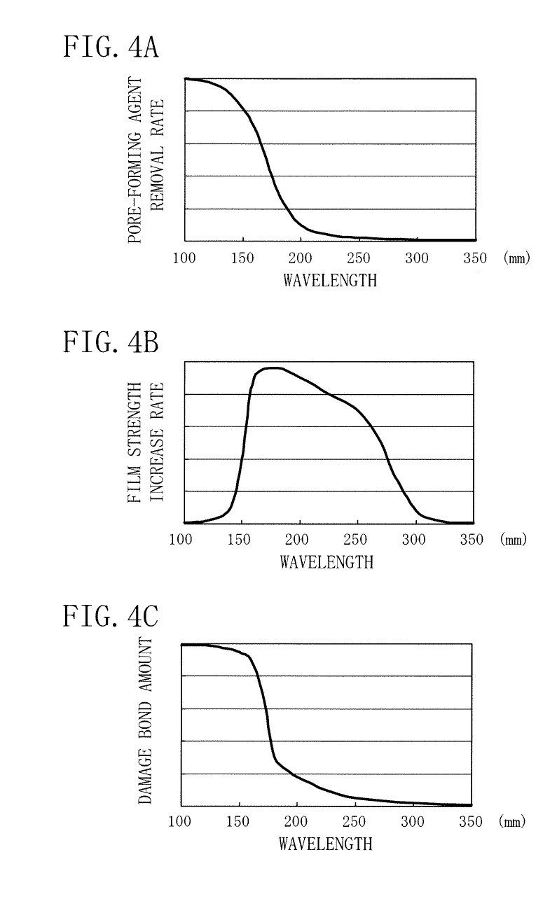

That is, it is preferable that the wavelengths of the first ultraviolet UV1 used in the first UV irradiation are shorter than the wavelengths of the second ultraviolet UV2 used in the second UV irradiation. More specifically, it is preferable that, while the first ultraviolet UV1 having a wavelength of about 200 nm or less as a main component is used in the first UV irradiation, the second ultraviolet UV1 having a wavelength of about 200 nm or more as a main component is used in the second UV irradiation. The reason for this will be described with reference to FIGS. 4A-4C.

FIG. 4A shows the relationship between the wavelength of UV used for irradiation of an interlayer insulating film containing a pore-forming agent and the removal rate of the pore-forming agent. From FIG. 4A, it is found that, when the wavelength of UV used is about 200 nm or less, the removal rate of the pore-forming agent is very high. Although UV wavelengths of about 180 nm or less are more preferred from the standpoint of improvement of the throughput, wavelengths of about 200 nm or less will be enough. When the wavelength of UV used exceeds about 200 nm, the removal rate of the pore-forming agent becomes low.

FIG. 4B shows the relationship between the wavelength of UV used for irradiation of an interlayer insulating film and the increase rate of film strength. FIG. 4C shows the relationship between the wavelength of UV used for irradiation of an interlayer insulating film and the damage bond amount in the film. From FIG. 4B, it is found that, when the wavelength of UV used is about 300 nm or less, the film strength increases. From FIG. 4C, it is found that, when the wavelength of UV used is more than about 200 nm, the damage bond amount in the film decreases. Therefore, from the standpoint of decrease in the damage of the interlayer insulating film and enhancement in the mechanical strength thereof, it is desirable that the wavelength of UV used exceeds about 200 nm. As is found from FIG. 4B, the film strength sharply decreases when the wavelength of UV used is less than about 150 nm. It is therefore preferable that the wavelength of UV used is about 150 nm or more.

From the reason described above, it is preferable that the wavelength of the first ultraviolet UV1 used in the first UV irradiation is shorter than the wavelength of the second ultraviolet UV2 used in the second UV irradiation. Also, it is preferable that, while the first ultraviolet UV1 having a wavelength of about 200 nm or less as a main component is used in the first UV irradiation, the second ultraviolet UV2 having a wavelength of about 200 nm or more as a main component is used in the second UV irradiation.

More specifically, it is preferable that, while the first ultraviolet UV1 having a wavelength in the range of about 150 nm to about 200 nm as a main component is used in the first UV irradiation, the second ultraviolet UV2 having a wavelength in the range of about 200 nm to about 300 nm as a main component is used in the second UV irradiation. Accordingly, it is preferable that the main wavelength component of the first ultraviolet UV1 used in the first UV irradiation performed in the step shown in FIG. 2F is in the range of about 150 nm to about 200 nm. Also, it is preferable that the main wavelength component of the second ultraviolet UV2 used in the second UV irradiation performed in the step shown in FIG. 2G is in the range of about 200 nm to about 300 nm.

(Second Fabrication Method of Embodiment)

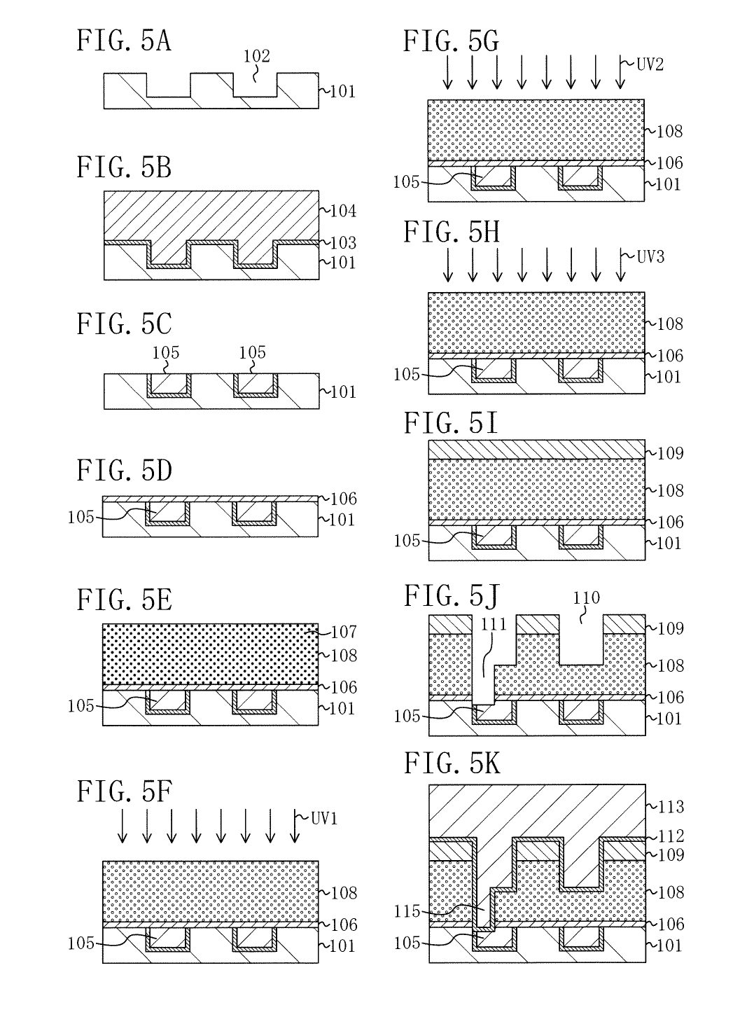

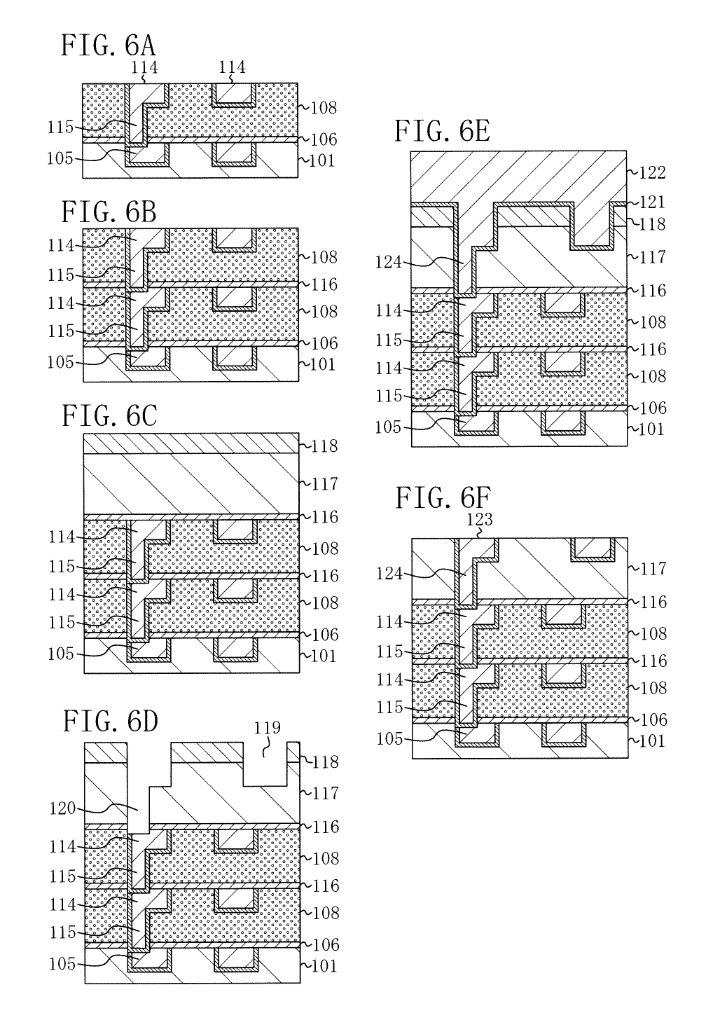

A second fabrication method for the semiconductor device of the embodiment of the present disclosure will be described with reference to FIGS. 5A-5K and 6A-6F. It should be noted that the materials and the values used in this fabrication method are not restrictive, but merely represent preferred examples, and that modifications can be made appropriately without departing from the spirit and scope of the present disclosure.

FIGS. 5A-5K and 6A-6F show cross-sectional configurations at steps of the second fabrication method for the semiconductor device of this embodiment.

Note that the steps shown in FIGS. 5A-5E are respectively the same as those shown in FIGS. 2A-2E in the first fabrication method and thus description of these steps is omitted here. Also, the steps shown in FIGS. 5I-5K and 6A-6F are respectively the same as those shown in FIGS. 2H-2J and 3A-3F in the first fabrication method and thus description of these steps is omitted here. In this fabrication method, therefore, the steps of FIGS. 5F-5H that are different from the first fabrication method will be described.

In FIG. 5E, a SiOC film 108 containing a pore-forming agent 107, having a thickness of about 200 nm, is formed on the first liner film 106 as the second interlayer insulating film. Thereafter, as shown in FIG. 5F, the SiOC film 108 is irradiated with first ultraviolet UV1 (first UV irradiation) to remove the pore-forming agent 107, thereby forming pores in the SiOC film 108. The first ultraviolet UV1 includes wavelength components of about 200 nm or less in a light quantity extremely large compared with wavelength components of more than about 200 mm, and has an illumination of about 100 mW/cm² to about 200 mW/cm². The resultant pore-formed SiOC film 108 has a relative dielectric constant of about 2.3 to about 2.5 and a modulus of elasticity of about 6 GPa to about 8 GPa, or less than this range. As the pore-forming agent 107, α-terpinene, which is a hydrocarbon-based material, is used. In this fabrication method, the removal rate of the pore-forming agent is improved by irradiation with short-wavelength UV light. This provides an advantage of improving the throughput of a semiconductor fabrication apparatus.

As shown in FIG. 5G, the SiOC film 108 is then irradiated with second ultraviolet UV2 having wavelengths different from those of the first ultraviolet UV1 (second UV irradiation) to improve the mechanical strength of the SiOC film 108. The second ultraviolet UV2 includes wavelength components of about 200 nm or more in a light quantity extremely large compared with wavelength components of less than about 200 mm, and has an illumination of about 100 mW/cm² to about 200 mW/cm². The resultant SiOC film 108 after the second UV irradiation has a relative dielectric constant of about 2.3 to about 2.5 and a modulus of elasticity of about 6 GPa to about 8 GPa or more. With this multi-stage UV irradiation performed in a plurality of separate times, the second interlayer insulating film 108 with low dielectric constant and high strength can be obtained.

Thereafter, as shown in FIG. 5H, the SiOC film 108 is further irradiated with third ultraviolet UV3 having wavelengths different from the above ones (third UV irradiation) to remove damage bonds in the SiOC film 108. The third ultraviolet UV3 includes wavelength components of about 300 nm or more in a light quantity extremely large compared with wavelength components of less than about 300 mm, and has an illumination of about 50 mW/cm² to about 150 mW/cm². By removing damage bonds by the third UV irradiation, the resistance against plasma damage improves during subsequent etching or ashing process. In this multi-stage UV irradiation, in which the roles played in changing the film quality are different among of the wavelengths, an equal film quality can be obtained even when the order of wavelengths used for irradiation is changed. Since the capacitance between interconnects can be reduced with decrease in the relative dielectric constant of the second interlayer insulating film 108, high-speed operation and low power can be achieved for the semiconductor device.

The damage bonds as used herein refer to hydrogen-related bonding groups in a SiOC film, or to be more specific, are Si—H bonds and Si—OH bonds. Existence of H and OH in a film puts the film in an unstable bonding state, causing problems of moisture absorption of the interlayer insulating film and degradation in plasma damage resistance thereof. Such damage bonds are inevitably formed as by-products of UV irradiation, and the dielectric constant will increase if damage bonds are left unremoved. It is therefore more preferable to remove such damage bonds. Note that the SiOC film refers to a SiO₂ film with a CH₃ group contained therein, which applies, not only to this fabrication method, but also to the embodiment and the other fabrication methods.

As described above, in the second fabrication method, the multi-stage UV irradiation is performed for the second interlayer insulating films 108 containing the pore-forming agent 107. More specifically, the first UV irradiation is performed using the first ultraviolet UV1 having wavelengths effective in speeding up the removal of the pore-forming agent, and the second UV irradiation is performed using the second ultraviolet UV2 having wavelengths effective in enhancing the mechanical strength of the second interlayer insulating film 108. Moreover, the third UV irradiation is performed using the third ultraviolet UV3 having wavelengths effective in removing damage bonds in the second interlayer insulating film 108. Since the first ultraviolet UV1, the second ultraviolet UV2, and the third ultraviolet UV3 are different in wavelength from one another as described above, reduction in dielectric constant and enhancement in mechanical strength can be achieved with good throughput.

That is, it is preferable that the wavelengths of the first ultraviolet UV1 used in the first UV irradiation are shorter than the wavelengths of the third ultraviolet UV3 used in the third UV irradiation. To put it the other way, it is preferable that the wavelengths of the third ultraviolet UV3 are longer than the wavelengths of the first ultraviolet UV1. More specifically, it is preferable that, while the first ultraviolet UV1 having a wavelength of about 200 nm or less as a main component is used in the first UV irradiation, the second ultraviolet UV2 having a wavelength of about 200 nm or more as a main component is used in the second UV irradiation, and the third ultraviolet UV3 having a wavelength of about 300 nm or more as a main component is used in the third UV irradiation.

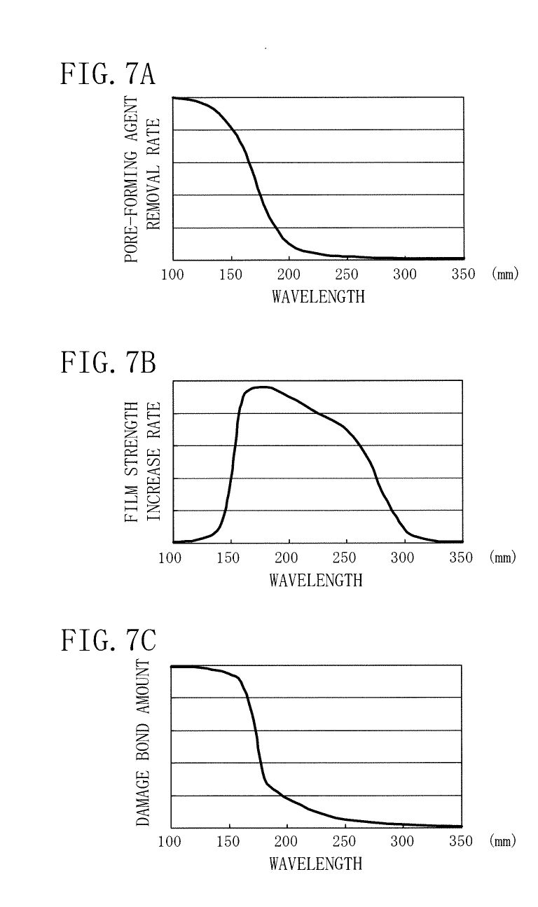

The wavelengths of the third ultraviolet UV3 used in the third UV irradiation will be described with reference to FIG. 7C. Note that as for the wavelengths used in the first UV irradiation and the second UV irradiation, which have been described in detail in the first fabrication method, description thereof is omitted here. Note also that, as for FIGS. 7A and 7B, which have been described in detail in the first fabrication method in conjunction with the wavelengths used in the first UV irradiation and the second UV irradiation, description thereof is omitted here.

FIG. 7C shows the relationship between the wavelength of UV used for irradiation of an interlayer insulating film containing a pore-forming agent and the damage bond amount. From FIG. 7C, it is found that, when the wavelength of UV used is about 300 nm or more, the damage bond amount is extremely small. For this reason, it is preferable that the wavelengths of the third ultraviolet UV3 used in the third UV irradiation are longer than the wavelengths of the first ultraviolet UV1 used in the first UV irradiation. To put it the other way, it is preferable that the wavelengths of the first ultraviolet UV1 are shorter than the wavelengths of the third ultraviolet UV3. It is also preferable to use the third ultraviolet UV3 having a wavelength of about 300 nm or more as a main component in the third UV irradiation. Since the upper limit of the wavelengths effective in removal of damage bonds is about 500 nm, it is more preferable to use UV having a wavelength in the range of about 300 nm to about 500 nm as a main component in the third UV irradiation. Accordingly, it is more preferable that the main wavelength component of the third ultraviolet UV3 in the third UV irradiation performed in FIG. 5H is in the range of about 300 nm to about 500 nm.

In the first and second fabrication methods described above, it is preferable to perform the multi-stage UV irradiation by emitting UV light from a light source of a single type.

It is also preferable that, when a wafer is to be irradiated with selected UV wavelengths at multiple stages, the irradiation is performed continuously in the same fabrication apparatus without moving the wafer.

Specific examples of the method and apparatus for UV irradiation used in common in the first and second fabrication methods will be described hereinafter in detail.

First Fabrication Apparatus

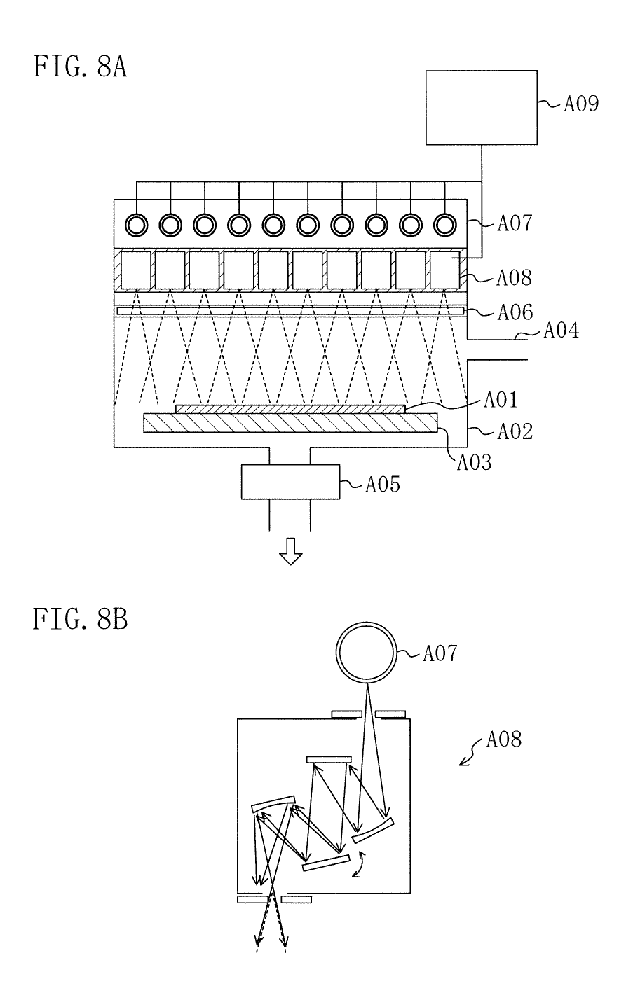

FIGS. 8A and 8B schematically show a first fabrication apparatus provided with spectroscopic devices that allow a wafer to be irradiated with UV light of selective wavelengths using a single type of light sources.

As shown in FIG. 8A, the first fabrication apparatus includes a reaction chamber A02 configured to contain a wafer (silicon substrate) A01, spectroscopic devices A08, and a UV lamp A07 as a light source.

The reaction chamber A02 has a holder A03 placed therein for holding the wafer A01, a gas feed port A04 placed on a side, a dry pump A05 placed on the bottom to serve as a gas exhaust port, and a quartz window A06 placed on a side.

Each of the spectroscopic devices A08, placed between the UV lamp A07 and the reaction chamber A02, includes a plurality of diffraction gratings as shown in FIG. 8B. The UV lamp A07 is comprised of an arrangement of a plurality of light sources of a single type. The UV lamp A07 and the spectroscopic devices A08 are connected to a control unit A09, which controls the angles of the plurality of diffraction gratings and the power supplied to the UV lamp, to permit arbitrary adjustment of the intensity of UV light of arbitrarily selected wavelengths.

In the first fabrication apparatus described above, the multi-stage UV irradiation can be achieved by irradiating the wafer A01 with UV light that has passed through the spectroscopic devices A08.

More specifically, the first UV irradiation is performed by setting the angles of the diffraction gratings of the spectroscopic devices A08 to predetermined first angles to obtain wavelengths effective in speeding up the removal of the pore-forming agent.

The second UV irradiation is performed by setting the angles of the diffraction gratings of the spectroscopic devices A08 to predetermined second angles to obtain wavelengths effective in enhancing the mechanical strength of the interlayer insulating film.

For the second fabrication method, the third UV irradiation is further performed by setting the angles of the diffraction gratings of the spectroscopic devices A08 to predetermined third angles to obtain wavelengths effective in removing damage bonds in the interlayer insulating film.

The holder A03 for holding the wafer A01 has a heating function. The heating temperature, which is changeable from room temperature up to about 600° C., for example, is set in the range of about 350° C. to about 400° C. in this fabrication apparatus.

In the reaction chamber A02, UV irradiation can be performed under a variety of gas atmosphere and pressure conditions. The reaction chamber A02 also has a function of cleaning the quartz window A06 after completion of UV irradiation of the wafer A01.

As the UV lamp A07, mercury, helium, deuterium, etc. may be used. In the illustrated fabrication apparatus, a mercury lamp is used.

Second Fabrication Apparatus

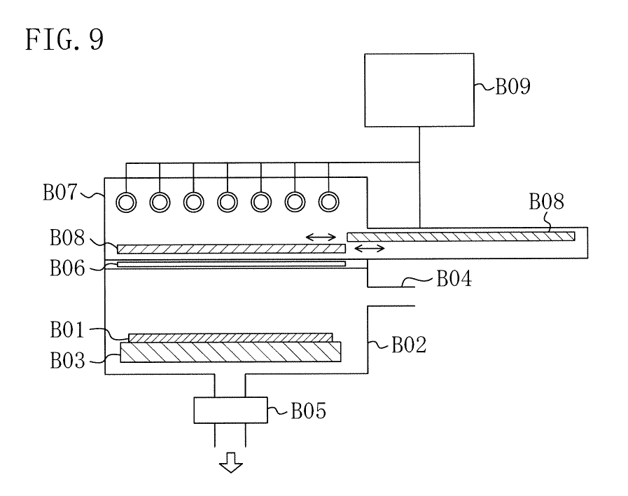

FIG. 9 schematically shows a second fabrication apparatus provided with a filter that allows a wafer to be irradiated with UV light of selective wavelengths using a single type of light sources.

As shown in FIG. 9, the second fabrication apparatus includes a reaction chamber B02 configured to contain a wafer (silicon substrate) B01, at least one filter B08, and a UV lamp B07 as a light source. The reaction chamber B02 has a holder B03 placed therein for holding the wafer B01, a gas feed port B04 placed on a side, a dry pump B05 placed on the bottom to serve as a gas exhaust port, and a quartz window B06 placed on a side.

The filter B08, placed between the UV lamp B07 and the reaction chamber B02, is movable in a direction parallel to the principal plane of the wafer B01 (in-plane direction of the principal plane of the silicon substrate). The UV lamp B07 is comprised of an arrangement of a plurality of light sources of a single type. The UV lamp B07 and the filter B08 are connected to a control unit B09, which controls presence/absence of the filter B08, the number of filters B08 used, and the power supplied to the UV lamp B07, to permit arbitrary adjustment of the intensity of UV light of arbitrarily selected wavelengths.

In the second fabrication apparatus described above, the multi-stage UV irradiation can be achieved by irradiating the wafer B01 with UV light that has passed through the filter B08.

More specifically, the first UV irradiation is performed using wavelengths effective in speeding up the removal of the pore-forming agent.

The second UV irradiation is performed by allowing UV light to pass through a first filter configured to give wavelengths effective in enhancing the mechanical strength of the interlayer insulating film.

For the second fabrication method, the third UV irradiation is further performed by allowing UV light to pass through a second filter configured to give wavelengths effective in removing damage bonds in the interlayer insulating film.

In the illustrated fabrication apparatus, prepared are the first and second filters configured to change wavelengths from the wavelengths used in the first UV irradiation, i.e., change wavelengths using the wavelengths used in the first UV irradiation as the reference. Alternatively, it is possible to prepare first and second filters configured to change wavelengths using the wavelengths used in the second UV irradiation as the reference. In this case, the first filter and the second filter will be respectively used in the first UV irradiation and the third UV irradiation. This also applies to the case of using the wavelengths used in the third UV irradiation as the reference.

The holder B03 for holding the wafer B01 has a heating function. The heating temperature, which is changeable from room temperature up to about 600° C., is set in the range of about 350° C. to about 400° C. in this fabrication apparatus.

In the reaction chamber B02, UV irradiation can be performed under a variety of gas atmosphere and pressure conditions. The reaction chamber B02 also has a function of cleaning the quartz window B06 after completion of UV irradiation of the wafer B01.

As the UV lamp B07, mercury, helium, deuterium, etc. may be used. In the illustrated fabrication apparatus, a mercury lamp is used.

It is preferable that the filter B08 is a movable band-pass filter.

Third Fabrication Apparatus

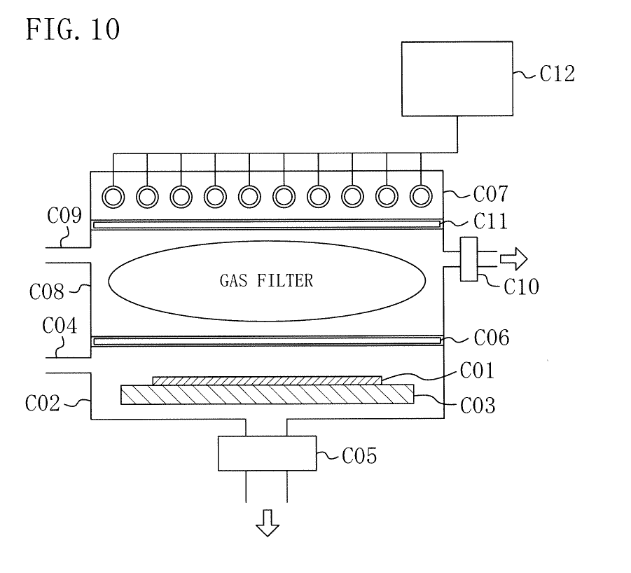

FIG. 10 schematically shows a third fabrication apparatus provided with a filter chamber that allows a wafer to be irradiated with UV light of selective wavelengths using a single type of light sources.

As shown in FIG. 10, the third fabrication apparatus includes a reaction chamber C02 configured to contain a wafer (silicon substrate) C01, a filter chamber C08 having a mechanism allowing a gas to be fed into and discharged from the reaction chamber C02, and a UV lamp C07 as a light source.

The reaction chamber C02 has a holder C03 placed therein for holding the wafer C01, a first gas feed port C04 placed on a side, a first dry pump C05 placed on the bottom to serve as a gas exhaust port, and a first quartz window C06 placed on a side.

The filter chamber C08, placed between the UV lamp C07 and the reaction chamber C02, has a second gas feed port C09, a second dry pump C10 serving as a gas exhaust port, and a second quartz window C11, each placed on a side.

The UV lamp C07 is comprised of an arrangement of a plurality of light sources of a single type. The UV lamp C07 and the filter chamber C08 are connected to a control unit C12, which controls the power supplied to the UV lamp C07 according to the atmosphere of the filter chamber C08, to permit arbitrary adjustment of the intensity of UV light of selected wavelengths.

In the third fabrication apparatus described above, the multi-stage UV irradiation can be achieved by irradiating the wafer C01 with UV light that has passed through the gas in the filter chamber C08.

That is, the first UV irradiation is performed by feeding, in the filter chamber C08, a gas capable of giving wavelengths effective in speeding up the removal of the pore-forming agent and allowing UV light to pass through the fed gas. An example of such a gas is nitrogen (N₂) gas. More specifically, it is preferable that, in the filter chamber C08, N₂ exists at a flow rate of 500 ml/min (0° C., 1 atm) and a pressure of 0.1 Pa to 100 Pa. Having such a gas, UV light having wavelengths of 200 nm or less is prevented from being absorbed by oxygen (O₂) in the atmosphere and losing the light intensity. Note that no problem will occur if the UV light is absorbed to some extent as far as the wafer C01 is irradiated with a light intensity of 100 mW/cm² to 200 mW/cm². Also, although the SiOC film may be irradiated with UV light having wavelengths of more than 200 nm, the film quality will not be degraded because the light amount of such UV light is minute.

The second UV irradiation is performed by feeding, in the filter chamber C08, a gas capable of giving wavelengths effective in enhancing the mechanical strength of the interlayer insulating film and allowing UV light to pass through the fed gas. An example of such a gas is oxygen (O₂) gas. More specifically, it is preferable that, in the filter chamber C08, O₂ exists at a flow rate of 5 l/min to 10 l/min (0° C., 1 atm) and a pressure of 1×10² Pa to 1×10⁵ Pa, although these values vary depending on the set light intensity. Having such a gas, UV light having wavelengths of less than 200 nm is absorbed by O₂ in the filter chamber C08 preventing the wafer C01 from being irradiated with such UV light.

For the second fabrication method, the third UV irradiation is further performed by feeding, in the filter chamber C08, a gas capable of giving wavelengths effective in removing damage bonds in the interlayer insulating film and allowing UV light to pass through the fed gas. Examples of such a gas include a mixed gas of oxygen (O₂) and tetramethylsilane (4MS) and a mixed gas of oxygen (O₂) and diethoxymethylsilane (DEMS). More specifically, it is preferable that, in the filter chamber C08, O₂ exists at a flow rate of 5 l/min to 10 l/min (0° C., 1 atm) and 4MS or DEMS at a flow rate of 1 l/min to 5 l/min (0° C., 1 atm) at a pressure of 1×10² Pa to 1×10⁵ Pa, although these values vary depending on the set light intensity. Having such a gas, UV light having wavelengths of less than 200 nm is absorbed by O₂ and also UV light having wavelengths in the range of 200 nm to 300 nm is absorbed by 4MS or DEMS, preventing the wafer C01 from being irradiated with such UV light.

The gas species used in the first UV irradiation, the second UV irradiation, and the third UV irradiation are not limited to those described above, but various gas species can be used as far as they can serve as a filter. Thus, by allowing a specific gas to absorb UV light of specific wavelengths, the wafer C01 can be irradiated with UV light of selective wavelengths.

It is preferable that the gas used in the UV irradiation at each stage is fed to flow inside the filter chamber C08.

The holder C03 for holding the wafer C01 has a heating function. The heating temperature, which is changeable from room temperature up to about 600° C., is set in the range of about 350° C. to about 400° C. in this fabrication apparatus.

In the reaction chamber C02, UV irradiation can be performed under a variety of gas atmosphere and pressure conditions. The reaction chamber C02 also has a function of cleaning the first quartz window C06 after completion of UV irradiation of the wafer C01.

As the UV lamp C07, mercury, helium, deuterium, etc. may be used. In the illustrated fabrication apparatus, a mercury lamp is used.

The second quartz window C11 is placed between the filter chamber C08 and the UV lamp C07, and the filter chamber C08 also has a function of cleaning the second quartz window C11 in addition to the role as the gas filter.

Although the first fabrication apparatus provided with the spectroscopic devices, the second fabrication apparatus provided with the filter, and the third fabrication apparatus provided with the filter chamber were described individually, the multi-stage UV irradiation may also be performed using a fabrication apparatus provided with at least two different types of devices, out of the spectroscopic devices, the filter, and the filter chamber, which are the features of the respective fabrication apparatuses, and any devices having functions equivalent to these features, as far as no contradiction occurs.

As described above, a semiconductor device with high yield, high reliability, and high performance can be implemented by any of the above fabrication apparatuses capable of performing multi-stage UV irradiation, or to be more specific, by a fabrication apparatus having any of a configuration permitting the first UV irradiation using the first ultraviolet UV1 having wavelengths effective in speeding up the removal of the pore-forming agent, a configuration permitting the second UV irradiation using the second ultraviolet UV2 having wavelengths effective in enhancing the mechanical strength of the interlayer insulating film, and a configuration permitting the third UV irradiation using the third ultraviolet UV3 having wavelengths effective in removing damage bonds in the interlayer insulating film.

(Third Fabrication Method of Embodiment)

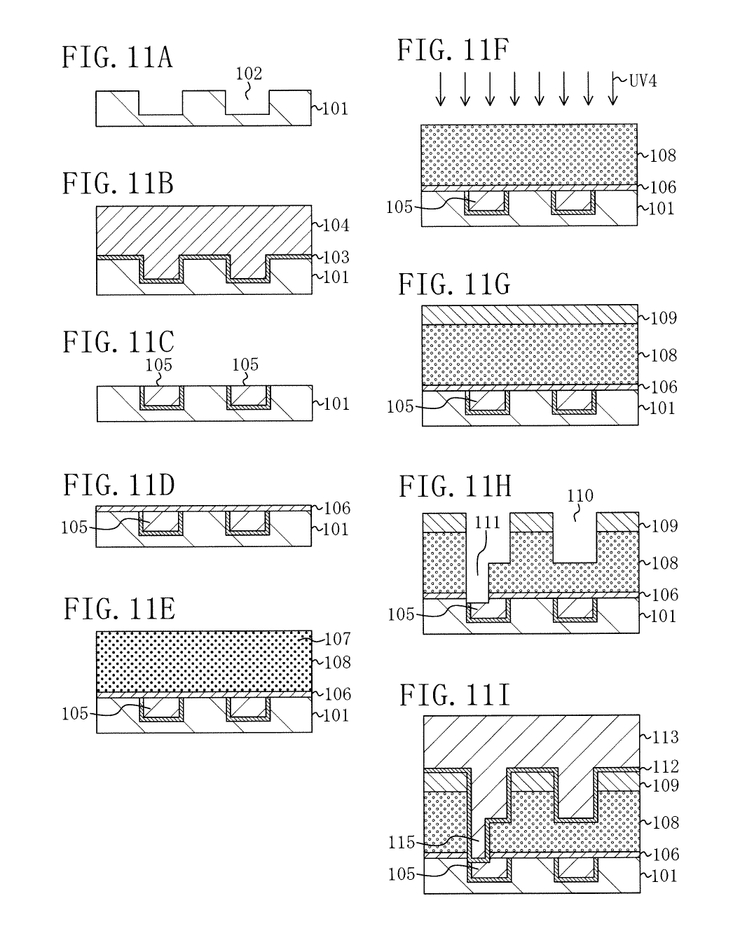

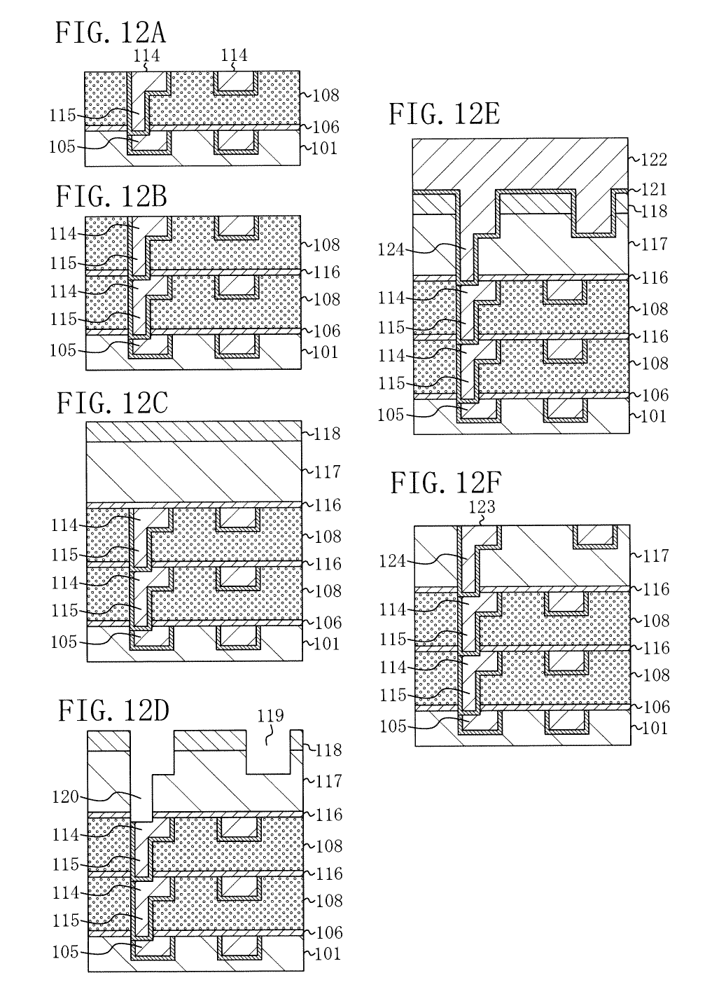

A third fabrication method for the semiconductor device of the embodiment of the present disclosure will be described with reference to FIGS. 11A-11I and 12A-12F. It should be noted that the materials and the values used in this fabrication method are not restrictive, but merely represent preferred examples, and that modifications can be made appropriately without departing from the spirit and scope of the present disclosure.

FIGS. 11A-11I and 12A-12F are cross-sectional views showing steps of the third fabrication method for the semiconductor device of this embodiment.

Note that the steps shown in FIGS. 11A-11E are respectively the same as those shown in FIGS. 2A-2E in the first fabrication method and thus description of these steps is omitted here. Also, the steps shown in FIGS. 11G-11I and 12A-12F are respectively the same as those shown in FIGS. 2H-2J and 3A-3F in the first fabrication method and thus description of these steps is omitted here. In this fabrication method, therefore, the step of FIG. 11F that is different from the first fabrication method will be described.

In FIG. 11E, a SiOC film 108 containing a pore-forming agent 107, having a thickness of about 200 nm, is formed on the first liner film 106 as the second interlayer insulating film.

Thereafter, as shown in FIG. 11F, the SiOC film 108 is irradiated with fourth ultraviolet UV4, to remove the pore-forming agent 107 thereby forming pores in the SiOC film 108, and also enhance the mechanical strength of the SiOC film 108. The fourth ultraviolet UV4 includes wavelength components in the range of about 180 nm to about 200 nm in a light quantity extremely large compared with the other wavelength components, and has an illumination of about 100 mW/cm² to about 200 mW/cm². The resultant pore-formed SiOC film 108 has a relative dielectric constant of about 2.3 to about 2.5 and a modulus of elasticity of about 6 GPa to about 8 GPa or more. As the pore-forming agent 107, α-terpinene, which is a hydrocarbon-based material, is used. With this UV irradiation, the second interlayer insulating film 108 with low dielectric constant and high strength can be obtained. Since the capacitance between interconnects can be reduced with decrease in the relative dielectric constant of the second interlayer insulating film 108, high-speed operation and low power can be achieved for the semiconductor device.

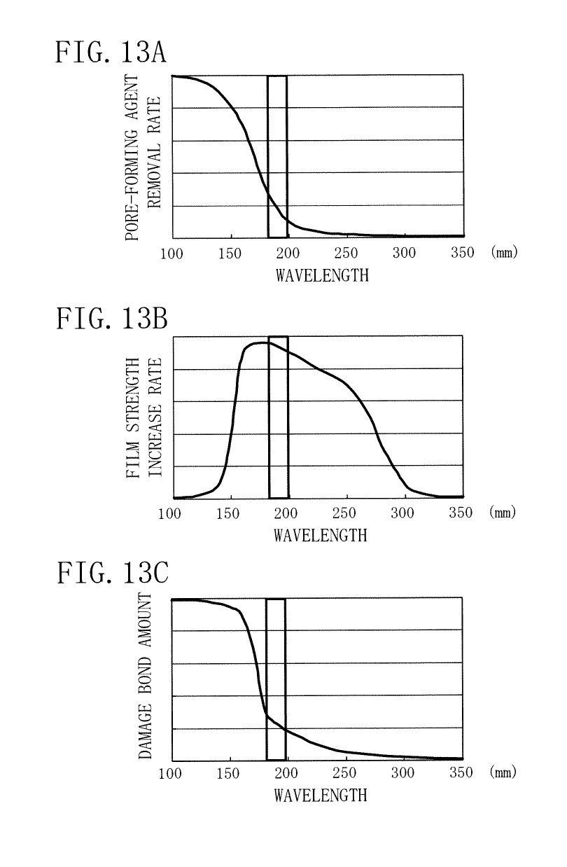

As described above, in the third fabrication method, the second interlayer insulating film 108 containing the pore-formation agent 107 is irradiated with UV only once. That is, irradiation is performed using the fourth ultraviolet UV4 having wavelengths effective in speeding up the removal of the pore-forming agent 107 and also enhancing the mechanical strength of the second interlayer insulating film 108. More specifically, it is preferable to use the fourth ultraviolet UV4 having a wavelength in the range of about 180 nm to about 200 nm as a main component. A light source for such irradiation can be obtained by dispersing argon plasma light emitted by laser excitation. In this way, if only wavelengths in a narrow wavelength range are used, reduction in dielectric constant and enhancement in mechanical strength can be achieved with good throughput. This is a technology unknown in Patent Document 1 described above. The reason for this achievement will be described with reference to FIGS. 13A-13C.

FIG. 13A shows the relationship between the wavelength of UV used for irradiation of an interlayer insulating film containing a pore-forming agent and the removal rate of the pore-forming agent. FIG. 13B shows the relationship between the wavelength of UV used for irradiation of an interlayer insulating film and the increase rate of film strength. FIG. 13C shows the relationship between the wavelength of UV used for irradiation of an interlayer insulating film and the damage bond amount in the film. From FIG. 13A, it is found that the wavelengths of UV must be about 200 nm or less to remove the pore-forming agent. From FIG. 13B, it is found that the wavelengths of UV must be in the range of about 150 nm to about 300 nm to increase the film strength, where the increase rate of the film strength is larger as the wavelength is shorter. From FIG. 13C, it is found that the damage bond amount is extremely large when the wavelength of UV used is less than about 180 nm, and conversely that the damage bond amount decreases with increase in wavelength when the wavelength of UV used is about 180 nm or more. From the above findings, it is found that a SiOC film with low dielectric constant, high strength, and reduced damage can be formed in one-time UV irradiation process by irradiating the SiOC film with the fourth ultraviolet UV4 having a wavelength in the range of about 180 nm to about 200 nm as a main component. This is effective in reducing the fabrication cost.

According to the semiconductor device and the fabrication method for the same of the present disclosure, increase in the relative dielectric constant of the insulating film and degradation in voltage resistance between interconnects are suppressed or reduced, and thus reduction in the yield and reliability of the semiconductor device can be prevented. In particular, the present disclosure is useful for an interconnect formation method of forming interconnects in an interlayer insulating film.

What is claimed is:

1. A fabrication method for a semiconductor device, comprising the steps of:
(a) forming a first interlayer insulating film containing a pore-forming agent on a semiconductor substrate; and
(b) irradiating the first interlayer insulating film with ultraviolet,
wherein
the step (b) includes the steps of
(b1) irradiating the first interlayer insulating film with first ultraviolet to remove the pore-forming agent contained in the first interlayer insulating film,
(b2) irradiating the first interlayer insulating film with second ultraviolet to enhance the mechanical strength of the first interlayer insulating film, and
(b3) irradiating the first interlayer insulating film with third ultraviolet to remove a damage bond generated in the first interlayer insulating film, and
a wavelength of the second ultraviolet in the step (b2) and a wavelength of the third ultraviolet in the step (b3) are different from each other.

2. The method of claim 1, wherein
the wavelength of the first ultraviolet is shorter than the wavelength of the third ultraviolet.

3. The method of claim 1, wherein
the first ultraviolet is ultraviolet having a wavelength in a range of 150 nm to 200 nm as a main component, and
the second ultraviolet is ultraviolet having a wavelength in a range of 200 nm to 300 nm as a main component.

4. The method of claim 1, wherein
the third ultraviolet is ultraviolet having a wavelength in a range of 300 nm to 500 nm as a main component.

5. The method of claim 1, wherein
the first interlayer insulating film has a relative dielectric constant of 2.5 or less and a pore diameter of 0.8 nm or more.

6. The method of claim 1, wherein
the pore-forming agent is a hydrocarbon-based material.

7. The method of claim 1, further comprising the step of:
(c) forming a plurality of first interconnects in the first interlayer insulating film before the step (b).

8. The method of claim 7, further comprising, after the step (c), the steps of:
(d) forming a second interlayer insulating film on the first interlayer insulating film; and
(e) forming a plurality of second interconnects in the second interlayer insulating film,
wherein
in the step (e), the second interlayer insulating film is not subjected to the ultraviolet irradiation in at least two separate times.

9. The method of claim 8, wherein
in the step (e), the second interlayer insulating film is not subjected to ultraviolet irradiation.

10. The method of claim 8, wherein
the spacing between the first interconnects is smaller than the spacing between the second interconnects.

11. The method of claim 1, wherein
a light source for the ultraviolet in the step (b) is of a single type.

12. The method of claim 1, wherein
the ultraviolet irradiation in at least two separate times in the step (b) is performed continuously in a same apparatus.

13. The method of claim 1, wherein
in the step (b), the ultraviolet irradiation is performed via a spectroscopic device configured to disperse the ultraviolet, placed between an ultraviolet lamp as a light source and the semiconductor substrate.

14. The method of claim 13, wherein
the spectroscopic device includes a diffraction grating, and
the ultraviolet is dispersed by adjusting the angle of the diffraction grating.

15. The method of claim 1, wherein
in the step (b), the ultraviolet irradiation is performed via a filter placed between an ultraviolet lamp as a light source and the semiconductor substrate.

16. The method of claim 15, wherein
the filter is placed movably in an in-plane direction of the principal plane of the semiconductor substrate.

17. The method of claim 1, wherein
in the step (b), the ultraviolet irradiation is performed via a gas provided between an ultraviolet lamp as a light source and the semiconductor substrate.

18. The method of claim 17, wherein
the gas is allowed to flow between the ultraviolet lamp and the semiconductor substrate.

19. A fabrication method for a semiconductor device, comprising the steps of:
(a) forming a first interlayer insulating film containing a pore-forming agent on a semiconductor substrate; and
(b) irradiating the first interlayer insulating film with ultraviolet,
wherein
the step (b) is executed by a fabrication apparatus including a configuration permitting irradiation using first ultraviolet having a wavelength effective in speeding up the removal of the pore-forming agent, a configuration permitting irradiation using second ultraviolet having a wavelength effective in enhancing the mechanical strength of the first interlayer insulating film, and a configuration permitting irradiation using third ultraviolet having a wavelength effective in removing a damage bond generated in the first interlayer insulating film.

20. A semiconductor device comprising:
a first interlayer insulating film formed on a semiconductor substrate, a plurality of first interconnects being formed in the first interlayer insulating film; and
a second interlayer insulating film formed on the first interlayer insulating film, a plurality of second interconnects being formed in the second interlayer insulating film, wherein
the dielectric constant of the first interlayer insulating film is lower than the dielectric constant of the second interlayer insulating film.

21. The device of claim 20, wherein
at least the first interlayer insulating film has pores, and
the porosity of the first interlayer insulating film is higher than the porosity of the second interlayer insulating film.

22. The device of claim 20, wherein
the film strength of the second interlayer insulating film is higher than the film strength of the first interlayer insulating film.

23. The device of claim 20, wherein
the spacing between the first interconnects is smaller than the spacing between the second interconnects.

24. The device of claim 20, wherein
a plurality of pores are formed in the first interlayer insulating film by removing a pore-forming agent.

25. The device of claim 20, wherein
the first interlayer insulating film is a carbon-containing silicon oxide film having a plurality of pores formed by removing a pore-forming agent.

26. The device of claim 20, wherein
the second interlayer insulating film is a silicon oxide film or a carbon-containing silicon oxide film.
